(19) United States
(12) Patent Application Publication
(10) Pub. No.: US 2026/0349050 A1
(43) Pub. Date: Nov. 5, 2026

(54) METHOD FOR DETERMINING SELF-HEALING AREA EFFECT OF METALLIZED FILM

(71) Applicant: HUAZHONG UNIVERSITY OF SCIENCE AND TECHNOLOGY, Hubei (CN)

(72) Inventors: Hua LI, Hubei (CN); Jing LAN, Hubei (CN); Tongwei ZHANG, Hubei (CN); Yibo WU, Hubei (CN); Fuchang LIN, Hubei (CN); Qin ZHANG, Hubei (CN); Yan WANG, Hubei (CN)

(73) Assignee: HUAZHONG UNIVERSITY OF SCIENCE AND TECHNOLOGY, Hubei (CN)

(21) Appl. No.: 19/433,948

(22) Filed: Dec. 28, 2025

Related U.S. Application Data
(63) Continuation of application No. PCT/CN2025/091994, filed on Apr. 29, 2025.

(30) Foreign Application Priority Data
Apr. 17, 2025 (CN) 202510483661.2

(51) Int. Cl. G01R 31/64

(52) U.S. Cl. CPC G01R 31/64

(57) ABSTRACT

A method for determining a self-healing area effect of a metallized film is provided. The method includes: preparing metallized film samples with different areas, conducting breakdown and a self-healing experiment to obtain data groups of breakdown field strengths and corresponding self-healing characteristic parameters with the different areas; determining an expression of the self-healing characteristic parameters with the breakdown field strengths and the areas of the metallized film samples according to the data groups, and simultaneously determining distribution properties of the self-healing characteristic parameters according to distribution properties of the breakdown field strengths; and obtaining a relationship between the self-healing characteristic parameters and the areas of the metallized films according to an area effect of the breakdown field strengths and the distribution properties of the self-healing characteristic parameters.

### CROSS-REFERENCE TO RELATED APPLICATION

This application is a continuation of international application of PCT application serial no. PCT/CN2025/091994, filed on Apr. 29, 2025, which claims the priority benefit of China application serial no. 202510483661.2, filed on Apr. 17, 2025. The entirety of each of the above-mentioned patent application is hereby incorporated by reference herein and made a part of this specification.

### BACKGROUND

### Technical Field

The present disclosure pertains to the technical field of testing metallized film capacitors, specifically relating to a method for determining a self-healing area effect of metallized films.

### Description of Related Art

The self-healing characteristic of metallized film is a crucial indicator for assessing the insulation reliability and lifespan of metallized film capacitors. For metallized films, accurately estimating their self-healing properties for appropriate insulation design is essential to prevent the risk of short-circuit breakdown failures in capacitors.

In estimating the self-healing characteristics of metallized films, the self-healing area effect is an unavoidable issue in engineering. The self-healing area effect refers to a phenomenon where the self-healing performance declines as the area of the metallized film increases. In the testing methods proposed by relevant standards, the test subjects are generally small-area metallized films, specifically those with an area less than 20 cm². However, in practical engineering applications, the area of metallized film capacitors may be 100 to 1000 times, or even tens of thousands of times, larger than the test subjects. In such cases, the increase in the area of the metallized film may lead to a significant decline in self-healing performance. If test results are directly used as a reference, there is a risk of capacitors having a shorter lifespan or even encountering short-circuit sintering in engineering applications. Therefore, it is extremely important to fully consider the impact of the self-healing area effect in order to accurately predict the self-healing characteristics of large-area metallized films.

Conventional methods for calculating the self-healing area effect are based on simple empirical formulas, such as assuming that a self-healing energy follows a power-law relationship with the area. However, these methods fail to account for a significant correlation between a breakdown field strength and self-healing characteristic parameters, resulting in empirical formulas derived from experimental data that are hardly applicable in practice. The calculated results are significantly higher than actual values, leading to overly conservative capacitor parameter designs with excessively large safety margins. Furthermore, conventional methods disregard distribution properties of the self-healing characteristic parameters, causing the calculated results to inaccurately represent the dispersion of these parameters.

### SUMMARY

The objective of the present disclosure is to provide a method for determining a self-healing area effect of a metallized film. This method is based on a correlation between breakdown field strength and self-healing characteristic parameters, as well as distribution properties of the self-healing characteristic parameters. The method of the present disclosure establishes a relationship between the self-healing characteristic parameters and an area of the metallized film, thereby providing a crucial basis for the design and application of large-area metallized films.

To achieve the above purpose, the present disclosure provides a method for determining the self-healing area effect of the metallized film, including:
step S1: preparing metallized film samples with different areas, conducting a breakdown and self-healing experiment, and obtaining data groups of breakdown field strengths and corresponding self-healing characteristic parameters at the different areas;
step S2: determining an expression of the self-healing characteristic parameters with the breakdown field strengths and the areas of the metallized film samples according to the data groups, and simultaneously determining distribution properties of the self-healing characteristic parameters according to distribution properties of the breakdown field strengths;
step S3: obtaining a relationship between the self-healing characteristic parameters and the areas of the metallized films according to an area effect of the breakdown field strengths and the distribution properties of the self-healing characteristic parameters.

Further, in step S1, two of the metallized film samples are placed with their metal surfaces facing upward and stacked, and then placed in a metallized film self-healing device to conduct the breakdown and self-healing experiment. A stacked area is an area A of the metallized film samples.

Further, in step S1, the metallized film sample is a polymer thin film with a metal film plated on a surface thereof. A thickness of the polymer thin film is 1 μm to 20 μm. The metal film is a zinc film or an aluminum film, and a thickness thereof is 2 nm to 20 nm.

Further, the polymer thin film is a PP thin film, a PET thin film, a PEN thin film or a PI thin film.

Further, in step S1, the number of the metallized film samples corresponding to each of the areas is not less than 30 groups. The area of the metallized film sample is 10 cm² to 80 cm².

Further, in step S1, the self-healing characteristic parameters include a self-healing energy Wₛₕ, a self-healing area Sₛₕ, and a self-healing duration tₛₕ.

Further, in step S2, an expression of the self-healing characteristic parameters with the breakdown field strengths and the areas of the metallized film samples is as follows:

Cₛₕ=g₁(E_{b})·g₂(A)

In the expression, Cₛₕ is the self-healing characteristic parameter, E_{b} is the breakdown field strength, g₁(E_{b}) is a relationship function of the self-healing characteristic parameter and the breakdown field strength, g₂(A) is a relationship function of the self-healing characteristic parameter and the area, g₁(E_{b}) and g₂(A) are power exponents or linear functions, which are fit through the data groups.

Further, an expression of the self-healing energy Wₛₕ in the self-healing characteristic parameter with the breakdown field strength and the area of the metallized film sample is as follows:

$${W}_{sh} = {mE}_{b}^{n} \cdot kA \qquad ( 1 )$$

In the expression, m, n, k are constant coefficients, and their values are fit through the data groups.

Further, the distribution properties of the breakdown field strengths are a Weibull distribution, a normal distribution or a Gumbel distribution. A form of the Weibull distribution is as follows:

$$F ( {E}_{b} ) = 1 - exp [ - {( \frac{{E}_{b}}{α} )}^{β} ] \qquad ( 2 )$$

In the expression, F(E_{b}) represents a cumulative probability of the breakdown field strength E_{b}, α is a scale parameter, and β is a shape parameter.

The breakdown field strength E_{b} in the expression (1) is substituted into the expression (2) to obtain the distribution properties of the self-healing energy Wₛₕ:

$$F ( {W}_{sh} ) = 1 - exp \{ - {[ \frac{{W}_{sh}^{\frac{1}{n}}}{{α ( mkA )}^{\frac{1}{n}}} ]}^{β} \} . \qquad ( 3 )$$

Further, the area effect of the breakdown field strength is obtained by adopting the Weibull distribution:

$$\{ \begin{matrix}\frac{{α}_{1}}{{α}_{2}} = {( \frac{{A}_{1}}{{A}_{2}} )}^{\frac{1}{{β}_{2}}} \\ {β}_{1} = {β}_{2}\end{matrix} \qquad ( 4 )$$

In the expression, α₁ and β₁ respectively represent a Weibull distribution scale parameter and a shape parameter under an area A₁, α₂ and β₂ respectively represent a Weibull distribution scale parameter and a shape parameter under an area A₂.

Further, according to data obtained from the experiment of the metallized film samples with one group of the areas, values of α and β under the area in the expression (2) are determined. The α and β under the area serve as α₂ and β₂ in the expression (4), the corresponding area serves as A₂ in the expression (4) and is substituted into the expression (4) to obtain the α₁ and β₁, and the α₁ and β₁ are substituted into the α and β respectively in the expression (3), and a cumulative probability F(Wₛₕ) of the expression (3) is set to 63.2% to obtain a relationship expression between the self-healing energy and the area.

Overall, compared with the related art, the above technical solution conceived by the present disclosure mainly has the following technical advantages:

1. The method for determining the self-healing area effect of the metallized film provided by the present disclosure obtains the relationship between the self-healing characteristic parameters and the areas based on the relationship between the breakdown field strengths and the self-healing characteristic parameters as well as the distribution properties of the self-healing characteristic parameters. The entire derivation process is scientific and rigorous, and the calculation is accurate and easy to conduct, providing an important basis for the design and application of large-area metallized films.

2. Further, the present disclosure adopts the Weibull distribution to determine the distribution properties of the breakdown field strengths, and meanwhile fits the relationship among the self-healing characteristic parameters, the breakdown field strengths and the areas according to the data obtained from the breakdown and self-healing experiments, then the data is combined with the breakdown field strength area effect and is substituted into the distribution properties of the breakdown field strengths to obtain the distribution properties of the self-healing characteristic parameters. In this way, the relationship between the self-healing characteristic parameters and the areas may be obtained according to the cumulative probability. The method of the present disclosure is applicable to the determination of the self-healing area effect of various metallized films and has a high universality.

### BRIEF DESCRIPTION OF THE DRAWINGS

FIG. 1 is a flow chart of a self-healing area effect of a metallized film provided by an embodiment of the present disclosure.

FIG. 2 is a calculation result diagram of a self-healing energy of a metallized film provided by an embodiment of the present disclosure.

### DESCRIPTION OF THE EMBODIMENTS

In order to make the objectives, technical solutions, and advantages of the present disclosure more clear and comprehensible, the following provides a further detailed description of the disclosure, in conjunction with the accompanying drawings and embodiments. It should be understood that the specific embodiments described herein are merely intended to explain the disclosure and are not meant to limit it. Furthermore, the technical features involved in the various embodiments of the disclosure described below may be combined with each other as long as there is no conflict between them.

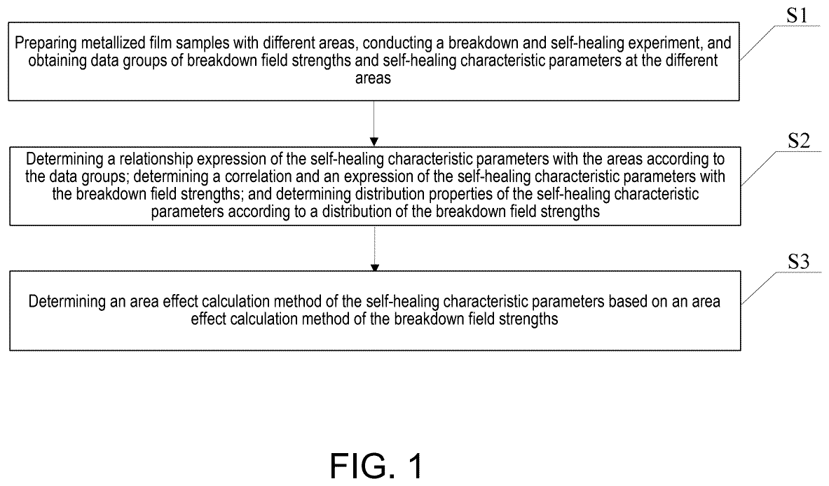

Referring to FIG. 1, which is a flow chart of a method for determining a self-healing area effect of a metallized film provided by an embodiment of the present disclosure. The method for calculating a dimensional effect of dielectric breakdown is described in detail below, and the method includes steps S1 to S3.

In step S1, metallized film samples with different areas are prepared to conduct breakdown and self-healing experiments to obtain data groups of breakdown field strengths and corresponding self-healing characteristic parameters under the different areas. The metallized film is a polymer thin film with a metal film plated on a surface thereof. The polymer film is a polypropylene thin film, a PET thin film, a PEN thin film, a PI thin film, etc., with a thickness of 1 μm to 20 μm. The metal film is a zinc film or an aluminum film, with a thickness of 2 nm to 20 nm. The area of the metallized film sample is 10 cm² to 100 cm², such as 10 cm², 12 cm², 16 cm², 18 cm², 20 cm², 24 cm², 28 cm², 30 cm², 32 cm², 36 cm², 40 cm², 46 cm², 48 cm², 64 cm², 80 cm², and so on.

The environmental conditions for metallized film testing should be close to the operating or application conditions to reduce the interference of environmental conditions on the calculation of an area effect. The breakdown field strengths and the self-healing characteristic parameters obtained from testing should include no less than 30 groups of data, preferably 40 to 80 groups, in order to reduce the interference of randomness on the calculation of the area effect.

The experimental variable is solely an area A, and there are at least two condition groups, with other conditions such as temperature, pressure, and metallized film material remaining constant. The metallized film samples for the breakdown and self-healing experiments employ a double-layer stacked structure, with an overlapping area corresponding to the area A. The double-layer stacked structure involves placing two of the metallized film samples with their metal surfaces facing upward and stacked upon each other, then subjecting them to the breakdown and self-healing experiments within a metallized film self-healing device (for details, please refer to the previously filed China patent application CN202311346617.4, which discloses a device and method for breakdown and self-healing of metallized films under direct current voltage).

The self-healing characteristic parameters include common parameters such as a self-healing energy Wₛₕ, a self-healing area Sₛₕ, a self-healing duration tₛₕ, etc., which are obtained from experimental voltage and current waveforms and sample observation.

In step S2, a relationship expression between the self-healing characteristic parameter Cₛₕ and the breakdown field strength E_{b}, the area A is fit according to the experimental data of step S1, that is:

Cₛₕ=g₁(E_{b})·g₂(A) (1)

In the expression, Cₛₕ is the corresponding self-healing characteristic parameter, E_{b} is the breakdown field strength, g₁(E_{b}) is a relationship function between the self-healing characteristic parameter and the breakdown field strength, and the form may be determined through literature search and experimental data, such as power exponent, linear function and other forms, g₂(A) is a relationship function between the self-healing characteristic parameter and the area, and the form is determined by experimental data, usually in the form of power exponent or linear function. For example, in some scenarios, the self-healing energy Wₛₕ, the breakdown field strength E_{b}, and the area A conform to the following relationship:

$${W}_{sh} = {mE}_{b}^{n} \cdot kA \qquad ( 2 )$$

In the expression, m, n, k are constant coefficients.

Subsequently, the distribution properties of the self-healing characteristic parameters are determined. These distribution properties of the self-healing characteristic parameters are derived from the distribution properties of the breakdown field strength and the expression between the self-healing characteristic parameters and the breakdown field strength. A cumulative probability distribution of the breakdown field strength satisfies:

F(E_{b})=g₃(E_{b}) (3)

In the expression, F(E_{b}) represents the cumulative probability of the breakdown field strength E_{b}, g₃(E_{b}) is a form of cumulative probability distribution of the breakdown field strength, usually determined by literature search or experimental data, including a Weibull distribution, a normal distribution, a Gumbel distribution, etc. The most common form of distribution is the Weibull distribution, which is:

$$F ( {E}_{b} ) = 1 - exp [ - {( \frac{{E}_{b}}{α} )}^{β} ] \qquad ( 4 )$$

In the expression, α is a scale parameter, and β is a shape parameter. The expression (2) between the self-healing characteristic parameter and the breakdown field strength and the area is substituted into the above expression (4), it is possible to obtain the form of distribution of the self-healing characteristic parameter, that is:

F(Cₛₕ)=g₄(Cₛₕ) (5)

In the expression, F(Cₛₕ) represents a cumulative probability of the self-healing characteristic parameter Cₛₕ, and g₄(Cₛₕ) is a form of cumulative probability distribution of the self-healing characteristic parameter. For example, in some specific embodiments, a form of distribution of the self-healing energy Wₛₕ is as follows:

$$F ( {W}_{sh} ) = 1 - exp \{ - {[ \frac{{W}_{sh}^{\frac{1}{n}}}{{α ( mkA )}^{\frac{1}{n}}} ]}^{β} \} \qquad ( 6 )$$

In step S3, an area effect calculation method of the self-healing characteristic parameter Cₛₕ shall consider the area effect of the breakdown field strength based on the distribution properties of the self-healing characteristic parameter.

Specifically, the calculation method for the area effect of the breakdown field strength may be obtained by consulting literature or experimental data. It is preferable to use the calculation method for the area effect of the breakdown field strength based on the Weibull distribution, namely:

$$\{ \begin{matrix}\frac{{α}_{1}}{{α}_{2}} = {( \frac{{A}_{1}}{{A}_{2}} )}^{\frac{1}{{β}_{2}}} \\ {β}_{1} = {β}_{2}\end{matrix} \qquad ( 7 )$$

In the expression, α₁ and β₁ respectively represent a Weibull distribution scale parameter and a shape parameter under an area A₁, α₂ and β₂ respectively represent a Weibull distribution scale parameter and a shape parameter under an area A₂. By substituting the expression (7) for the area effect of the breakdown field strength into the distribution expression (6) for the self-healing characteristic parameter, it is possible to derive the calculation method for the area effect of the self-healing characteristic parameter.

The following provides a specific example to illustrate this method. Polypropylene films with a uniform thickness of d (6 μm) and areas of 16 cm², 32 cm², and 48 cm² are employed as samples (the metal film is an aluminum film with a thickness of 7 nm). Experiments were conducted based on the breakdown self-healing of double-layer metallized films and experimental methods (specifically referenced in the previously filed China patent application CN202311346617.4, which discloses a device and method for self-healing of metallized films under direct current voltage). The breakdown field strength and the self-healing energy of the samples were measured, with each film area having 60 measurement samples. Based on the obtained data group, a power exponential and linear relationship function were used to fit the relationship between the self-healing energy Wₛₕ, the breakdown field strength E_{b}, and the area A, resulting in mk=0.076×10⁻⁷, n=2.8, which indicates:

$${W}_{sh} = 0.076 \times 1 {0}^{- 7} {E}_{b}^{2.8} A \qquad ( 8 )$$

Fitting the breakdown field strength distribution using the Weibull distribution yields parameters α=622V/μm and β=7.2 for an area of 32 cm² (it is noteworthy that parameters may also be derived from data pertaining to other experimental areas, typically equal to or greater than 10 cm², with a resulting discrepancy in the relationship between the self-healing energy and the area being within 5%). According to the predictive method for the area effect on the breakdown field strength, the breakdown distribution parameters for other areas may be determined as follows:

$$\{ \begin{matrix}\frac{α}{622} = {( \frac{A}{32} )}^{- \frac{1}{7.2}} \\ β = 7.2\end{matrix} \qquad ( 9 )$$

By substituting the area effect laws of α and β into the self-healing energy distribution expression (6), the following may be obtained:

$$F ( {W}_{sh} ) = 1 - exp \{ - {[ \frac{{W}_{sh}^{\frac{1}{2.8}}}{622 \times {( \frac{A}{32} )}^{- \frac{1}{7.2}} \times {( 0.076 \times 1 {0}^{7} A )}^{\frac{1}{2.8}}} ]}^{7.2} \} \qquad ( 10 )$$

The area effect of the self-healing energy may be calculated using the calculation method for breakdown field strength area effect based on the Weibull distribution. The self-healing energy Wₐ, corresponding to a cumulative probability of 63.2% (i.e., when Expression 10 equals 63.2%), is selected as the parameter representing the overall self-healing energy. The expression is as follows:

$${W}_{a}^{\frac{1}{n}} = {α ( mkA )}^{\frac{1}{n}} ⇔ {W}_{a} = {[ 622 \times {( \frac{A}{32} )}^{- \frac{1}{7.2}} ]}^{2.8} \times 0.076 \times {10}^{- 7} A \qquad ( 11 )$$

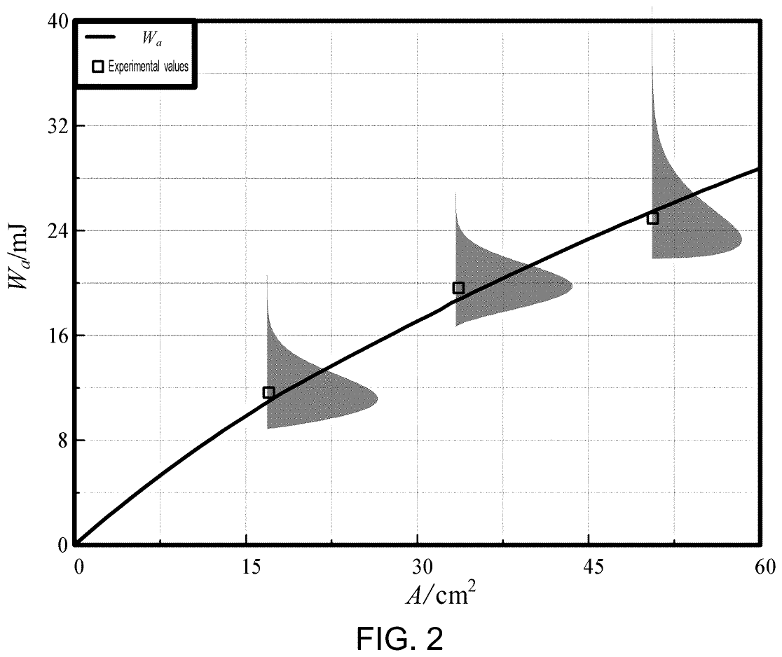

The calculation curves under different areas ultimately obtained are shown in FIG. 2.

In summary, the method for determining the self-healing area effect of a metallized film provided by the present disclosure reasonably considers the relationship between the breakdown field strength and the self-healing characteristic parameters, as well as the distribution properties of the self-healing characteristic parameters. This approach establishes the relationship between the self-healing characteristic parameters and the area. The entire derivation process is scientifically rigorous, the calculations are accurate and feasible, and possesses a high universality. This provides an important basis for the design and application of large-area metallized films.

It will be understood by those skilled in the art that the above description merely constitutes a preferred embodiment of the present disclosure and is not intended to limit the disclosure. Any modifications, equivalent substitutions, and improvements made within the spirit and principles of the present disclosure should be encompassed within the scope to be protected by the present disclosure.

What is claimed is:

1. A method for determining a self-healing area effect of a metallized film, comprising:
step S1: preparing metallized film samples with different areas, conducting a breakdown and self-healing experiment, and obtaining data groups of breakdown field strengths and corresponding self-healing characteristic parameters at the different areas;
step S2: determining an expression of the self-healing characteristic parameters with the breakdown field strengths and the areas of the metallized film samples according to the data groups, and simultaneously determining distribution properties of the self-healing characteristic parameters according to distribution properties of the breakdown field strengths;
step S3: obtaining a relationship between the self-healing characteristic parameters and the areas of the metallized films according to an area effect of the breakdown field strengths and the distribution properties of the self-healing characteristic parameters.

2. The method for determining the self-healing area effect of the metallized film according to claim 1, wherein in the step S1, two of the metallized film samples are placed with their metal surfaces facing upward and stacked, and then placed in a metallized film self-healing device to conduct the breakdown and self-healing experiment, a stacked area is an area A of the metallized film samples.

3. The method for determining the self-healing area effect of the metallized film according to claim 1, wherein in the step S1, the metallized film samples are a polymer thin film with a metal film plated on a surface thereof, a thickness of the polymer thin film is 1 μm to 20 μm, the metal film is a zinc film or an aluminum film, and a thickness thereof is 2 nm to 20 nm;
and/or, the polymer thin film is a PP thin film, a PET thin film, a PEN thin film or a PI thin film.

4. The method for determining the self-healing area effect of the metallized film according to claim 1, wherein in the step S1, a number of the metallized film samples corresponding to each of the areas is not less than 30 groups, and the areas of the metallized film samples is 10 cm² to 80 cm².

5. The method for determining the self-healing area effect of the metallized film according to claim 1, wherein in the step S1, the self-healing characteristic parameters comprise a self-healing energy Wₛₕ, a self-healing area Sₛₕ, and a self-healing duration tₛₕ.

6. The method for determining the self-healing area effect of the metallized film according to claim 1, wherein in the step S2, an expression of the self-healing characteristic parameters with the breakdown field strengths and the areas of the metallized film samples is as follows:
Cₛₕ=g₁(E_{b})·g₂(A) (1)
wherein, Cₛₕ is the self-healing characteristic parameter, E_{b} is the breakdown field strength, g₁(E_{b}) is a relationship function of the self-healing characteristic parameter and the breakdown field strength, g₂(A) is a relationship function of the self-healing characteristic parameter and the area, g₁(E_{b}) and g₂(A) are power exponents or linear functions, which are fit through the data groups, and A is the area of the metallized film sample.

7. The method for determining the self-healing area effect of the metallized film according to claim 6, wherein an expression of the self-healing energy Wₛₕ in the self-healing characteristic parameter with the breakdown field strength and the area of the metallized film sample is as follows:
$${W}_{sh} = {mE}_{b}^{n} \cdot kA \qquad ( 2 )$$
wherein, m, n, k are constant coefficients, and their values are fit through the data groups.

8. The method for determining the self-healing area effect of the metallized film according to claim 7, wherein the distribution properties of the breakdown field strengths are a Weibull distribution, a normal distribution or a Gumbel distribution, and a form of the Weibull distribution is as follows:
$$F ( {E}_{b} ) = 1 - exp [ - {( \frac{{E}_{b}}{α} )}^{β} ] \qquad ( 3 )$$
wherein F(E_{b}) represents a cumulative probability of the breakdown field strength E_{b}, α is a scale parameter, and β is a shape parameter;
the breakdown field strength E_{b} in the expression (2) is substituted into the expression (3) to obtain distribution properties of the self-healing energy Wₛₕ:
$$F ( {W}_{sh} ) = 1 - exp \{ - {[ \frac{{W}_{sh}^{\frac{1}{n}}}{{α ( mkA )}^{\frac{1}{n}}} ]}^{β} \} . \qquad ( 4 )$$

9. The method for determining the self-healing area effect of the metallized film according to claim 8, wherein the area effect of the breakdown field strength is obtained by adopting the Weibull distribution:
$$\{ \begin{matrix}\frac{{α}_{1}}{{α}_{2}} = {( \frac{{A}_{1}}{{A}_{2}} )}^{\frac{1}{{β}_{2}}} \\ {β}_{1} = {β}_{2}\end{matrix} \qquad ( 5 )$$
wherein α₁ and β₁ respectively represent a Weibull distribution scale parameter and a shape parameter under an area A₁, α₂ and β₂ respectively represent a Weibull distribution scale parameter and a shape parameter under an area A₂.

10. The method for determining the self-healing area effect of the metallized film according to claim 9, wherein according to data obtained from the experiment of the metallized film samples with one group of the areas, values of α and β under the area in the expression (3) are determined, the α and β under the area serve as α₂ and β₂ in the expression (5), the corresponding area serves as A₂ in the expression (5) and is substituted into the expression (5) to obtain the α₁ and β₁, and the α₁ and β₁ are substituted into the α and β respectively in the expression (4), and a cumulative probability F(Wₛₕ) of the expression (4) is set to 63.2% to obtain a relationship expression between the self-healing energy and the area.
